(19) United States
(12) Patent Application Publication
(10) Pub. No.: US 2007/0278637 A1
(43) Pub. Date: Dec. 6, 2007

(54) Circuit Arrangement, System Carrier and Methods for Producing Same

(75) Inventors: Michael Bauer, Nittendorf (DE); Alfred Haimerl, Sinzing (DE); Angela Kessler, Regensburg (DE); Joachim Mahler, Regensburg (DE)

Correspondence Address: EDELL, SHAPIRO & FINNAN, LLC, 1901 RESEARCH BLVD., SUITE 400, ROCKVILLE, MD, 20850, US

(73) Assignee: Infineon Technologies AG, Neubiberg (DE)

(21) Appl. No.: 11/757,446

(22) Filed: Jun. 4, 2007

(30) Foreign Application Priority Data
Jun. 2, 2006 (DE) 10 2006 025 961.0

(51) Int. Cl. H01L 23/02; H01L 21/00

(52) U.S. Cl. 257/678; 438/106

(57) ABSTRACT

A circuit arrangement includes a component or an integrated circuit firmly attached on a wiring carrier via an adhesive layer. Furthermore, a pyrolytically deposited adhesion promoter layer with high surface energy and/or high porosity in the nanometer range is selectively provided on a metallic adherend location of the wiring carrier.

### CROSS REFERENCE TO RELATED APPLICATIONS

This application claims priority under 35 U.S.C. §119 to Application No. DE 102006025961.0 filed on Jun. 2, 2006, entitled “Semiconductor Circuit Arrangement, System Carrier and Method for Producing a System Carrier and a Semiconductor Circuit Arrangement,” the entire contents of which are hereby incorporated by reference.

### BACKGROUND

As in many other areas of technology, in recent years adhesive techniques have also been increasingly used in the production of electronic circuits. For certain applications, adhesive methods thereby replace conventional soldering or bonding methods as well as screw or crimp connections and others. Here it is generally required that the quality of the connection is at least equivalent to that of the previously used connecting technique. This also applies in particular to the reliability under extreme conditions of use and over long periods of time.

Similar requirements apply to techniques for the encapsulation of electronic components or circuits in plastic packages via what are known as molding compounds. Since, in the case of such packages, degradation caused by the sudden evaporation of moisture that can penetrate between a system carrier and the plastic package molding compound has been observed, the use of adhesion promoters at the interface between the system carrier and the molding compound has been proposed. Furthermore, semiconductor and/or metal oxides or silicate connections are proposed as suitable adhesion promoters. Among the semiconductor device components that may be embedded here are ceramic substrates, printed circuit boards with a structured metal coating or leadframes.

The use of adhesion promoters, SiN, SiO₂, SiC protective films or metal oxide adhesion layers with dentritic morphology in the packaging of semiconductor devices is also known. Furthermore, the galvanic application of adhesion promoter layers to the metallic portions of wiring substrates is also known.

It is also known to improve the adhesion of package resin on metals in the packaging of integrated circuits or multilayer printed circuit board structures by suitable combination of a specific metal (in particular copper, antimony or nickel-iron alloys) and a siliceous coating, which is formed by application of a strongly alkaline silicate solution to the selected metal and a subsequent electrochemical process.

Apart from the mentioned problems in the packaging of semiconductor devices or circuits in plastic packages (and the solution proposals discussed above), problems with the reliability of adhesive connections, specifically encountered with what is known as die bonding, have also become known. Problems with the reliability of corresponding adhesive connections have been found in particular with the use of bonding pads that are coated with precious metal.

### SUMMARY

An improved circuit arrangement and an improved system carrier of the generic type including a significantly improved quality of the associated adhesive connections in die-bonding regions and a method that is suitable for producing the same is described herein.

The circuit arrangement includes a component or an integrated circuit firmly attached on a wiring carrier via an adhesive layer. Furthermore, a pyrolytically deposited adhesion promoter layer with high surface energy and/or high porosity in the nanometer range is selectively provided on a metallic adherend location of the wiring carrier.

The above and still further features and advantages of the present invention will become apparent upon consideration of the following definitions, descriptions and descriptive figures of specific embodiments thereof, wherein like reference numerals in the various figures are utilized to designate like components. While these descriptions go into specific details of the invention, it should be understood that variations may and do exist and would be apparent to those skilled in the art based on the descriptions herein.

### BRIEF DESCRIPTION OF THE DRAWINGS

FIGS. 1A to 1C schematically show stages of the construction of a semiconductor circuit arrangement.

### DETAILED DESCRIPTION

The described device and method include selectively providing a nonmetallic adhesion promoter layer on an adherend location of the wiring carrier of the circuit arrangement or of a system carrier provided as a product to be further processed. Further described herein is the forming of this adhesion promoter layer with high surface energy and/or high porosity in the nanometer range (e.g., pores in the adhesion promoter layer having dimensions in the range of 100 nm or less).

Furthermore, the adhesion promoter layer can be a pyrolytically deposited layer. Accordingly, the proposed production method includes pyrolytically, in particular flame-pyrolytically, creating the adhesion promoter layer from an organometallic compound.

The nanoporous morphology of the adhesion promoter layer accordingly creates a nanomechanical interlocking of the surface of the adherend location with the adhesive layer to be applied, and it promotes the forming of chemical bridges between the adhesion promoter layer and the adhesive layer. After applying the adhesive layer, the structure of the adhesive molecules can superficially penetrate the adhesion-promoting coating, and consequently an elastic transitional layer forms between the surface of the adherend location of the system carrier and the adhesive layer. This transitional layer compensates for mechanical stresses that could arise as a result of the different coefficients of thermal expansion of the metallic material of the adherend location and the polymeric adhesive.

In an exemplary embodiment, the adhesion promoter layer has a thickness of well below 1 μm, for example, in the range from 5 nm to 200 nm, and optionally from 5 nm to 50 nm. For most applications, a thickness in the lower region of the stated range of values, for example, below 30-40 nm, will be adequate to achieve the aforementioned positive effects of the adhesion promoter layer, without the electrical and thermal properties of the construction being adversely influenced by this layer.

The adhesion promoter layer may comprise a silicate layer. The silicate layer can be applied easily and at low cost via a flame-pyrolytic method.

All adhesives that are known for use with semiconductor circuit arrangements or associated system carriers can be used within the scope of the invention, for example, those that are epoxy-based, or else adhesives that are based on acrylic resin, urethane resin or melamine resin. Adhesive compositions that can penetrate an existing nanoporous surface are also suitable.

The arrangement and method described herein are also suitable where the adherend location is formed by a chip pad with a precious metal surface with low surface energy (e.g., Ag, Au, Pd or Pt). Because of their very low surface energy, such chip pads with a precious metal surface entail to a high degree risks for the quality of an adhesive connection created directly on them. On the other hand, if the method is suitably conducted, the adhesion of the proposed intermediate layer on such surfaces is excellent, with the result that the micromechanical effects specified above can be readily achieved here. Likewise, other metallic surfaces, such as Cu, Al, Ni or NiP, are also suitable for the arrangement.

The method described herein includes depositing a silicate adhesion promoter layer with high surface energy and/or high porosity in the nanometer range onto an adherend location of a wiring carrier in a pyrolytic process, in that an organometallic compound in the presence of O₂ or an oxygen-containing compound and a fuel gas, in particular butane or propane, is subjected to a flame pyrolysis. The organometallic compound can be an organometallic silicon compound, (e.g., tetraethylsilane).

According to an exemplary embodiment of the adhesion promoter layer, it is provided that the flame pyrolysis can be ended as soon as a predetermined layer thickness of the adhesion promoter layer, for example, in the range from 5 nm to 200 nm, and optionally from 5 to 50 nm, has been deposited on the adherend location.

Optionally, it is provided that a metallic chip pad with a precious metal surface (e.g., Ag, Au, Pt or Pd) is provided as an adherend location. These materials can be used for wiring or system carriers in semiconductor technology and offer numerous advantages. The method described herein renders these materials suitable as an underlying surface for high-grade adhesive connections in die bonding, such that their use becomes less problematic and creates potentially wider applications.

Exemplary embodiments of the circuit arrangement, system carrier and methods are described in connection with the figures.

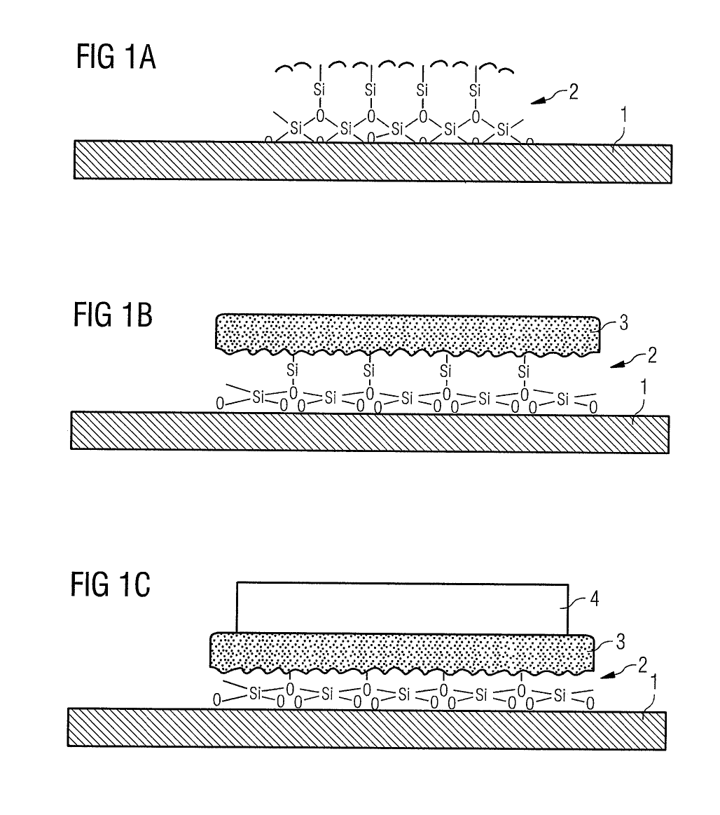

FIG. 1A schematically shows a leadframe 1 with a silicate layer 2 locally deposited on the leadframe in a pyrolytic manner.

The silicate layer is formed as SiOₓ on the surface of the leadframe, comprising for example, gold, by tetraethylsilane Si(C₂H₅)₄ being fed to a flame coating installation known per se, together with a fuel (for instance, propane gas C₃H₈) and oxygen, and burned thereon. In the process, SiOₓ silicates are deposited on the surface to be coated, while carbon dioxide and water are released. The setting of a desired layer thickness in the range stated above is performed by setting the reaction time or application time of the reaction gas mixture to the surface intended for silicate deposition; the application time, for example, lies in the range of seconds.

Such a flame coating method advantageously involves cleaning and activating the surface.

FIG. 1B shows the state of the arrangement after application of an adhesive layer 3. With the deformation of the silicate layer 2 that is shown schematically, the interfacial influence of the adhesive layer is present on the silicate layer 2. The silicates are capable of forming, via Si—C bonds, hydrolytically stable chemical bonds with the adhesive layer. In addition, the silicates also enter into stable bonds with the metallic underlying surface, and the nanoporosity of the surface structure on the one hand increases the reaction area and on the other hand creates nano-interlocking elements with respect to the adhesive layer.

Finally, FIG. 1C schematically shows the final state with, for example, a semiconductor chip 4 applied to the adhesive layer 3 and thereby, adhesively attached to the leadframe.

While the invention has been described in detail with reference to specific embodiments thereof, it will be apparent to one of ordinary skill in the art that various changes and modifications can be made therein without departing from the spirit and scope thereof. Accordingly, it is intended that the present invention covers the modifications and variations of this invention provided they come within the scope of the appended claims and their equivalents.

What is claimed:

1. A circuit arrangement comprising:
a wiring carrier including a surface with a metallic adherend location disposed on the surface;
an adhesion promoter layer pyrolytically deposited on the adherend location of the wiring carrier surface, wherein the adhesion promoter layer has a high surface energy or a high porosity in the nanometer range;
an adhesive layer applied to the adhesion promoter layer; and
a component secured to the wiring carrier via the adhesive layer.

2. The circuit arrangement according to claim 1, wherein the component comprises a semiconductor component or an integrated semiconductor circuit.

3. The circuit arrangement according to claim 1, wherein the adhesion promoter layer has a thickness less than 1 μm.

4. The circuit arrangement according to claim 1, wherein the adhesion promoter layer has a thickness from 5 nm to 200 nm.

5. The circuit arrangement according to claim 1, wherein the adhesion promoter layer has a thickness from 5 nm to 50 nm.

6. The circuit arrangement according to claim 1, wherein the adhesion promoter layer comprises a silicate layer.

7. The circuit arrangement according to claim 1, wherein the adherend location comprises a chip pad with a precious metal surface, wherein the metal surface comprises one of Ag, Au, Pt, Al and Ni.

8. A system carrier for a circuit arrangement, the system carrier comprising:
a substrate surface including a plurality of predetermined adherend locations disposed on the substrate surface to fix components to the system carrier via an adhesive connection; and
an adhesion promoter layer pyrolytically deposited on the adherend locations, wherein the adhesion promoter layer is a promotion layer with a high surface energy or a high porosity in the nanometer range.

9. The system carrier according to claim 8, wherein the components to be fixed to the system carrier are semiconductor components or integrated circuits.

10. The system carrier according to claim 8, wherein the adhesion promoter layer has a thickness less than 1 μm.

11. The system carrier according to claim 8, wherein the adhesion promoter layer has a thickness from 5 nm to 200 nm.

12. The system carrier according to claim 8, wherein the adhesion promoter layer has a thickness from 5 nm to 50 nm.

13. The system carrier according to claim 8, wherein the adhesion promoter layer comprises a silicate layer.

14. The system carrier according to claim 8, wherein each adherend location comprises a chip pad with a precious metal surface, wherein the metal comprises one of Ag, Au, Pt, Al and Ni.

15. A method for producing a system carrier for a circuit arrangement, the method comprising:
providing an adherend location on a surface of a wiring carrier; and
forming a silicate adhesion promoter layer onto the adherend location of the wiring carrier via a pyrolytic deposition process, wherein the silicate adhesion promoter layer has a high surface energy or high porosity in the nanometer range.

16. The method of claim 15, wherein the pyrolytic deposition process comprises subjecting an organometallic silicon compound in the presence of oxygen or an oxygen-containing compound and a fuel gas to flame pyrolysis.

17. The method according to claim 16, wherein the organometallic silicon compound comprises tetraethylsilane.

18. The method for producing a system carrier according to claim 16, wherein the fuel gas comprises butane or propane.

19. The method of claim 15, further comprising:
applying an adhesive layer to the adhesion promoter layer; and
securing a component to the adhesive layer so as to affix the component to the wiring carrier.

20. The method for producing a circuit arrangement according to claim 19, wherein the component comprises a semiconductor component or an integrated circuit.

21. The method according to claim 15, wherein the silicate adhesion promoter layer formed by the pyrolytic deposition process has a layer thickness from 5 nm and 200 nm.

22. The method according to claim 15, wherein the silicate adhesion promoter layer formed by the pyrolytic deposition process has a layer thickness from 5 nm to 50 nm, inclusive.

23. The method according to claim 15, wherein the adherend location comprises a metallic chip pad with a precious metal surface comprising one of Ag, Au, Pt, Pd, Al and Ni.
